(19) United States
(12) Patent Application Publication
(10) Pub. No.: US 2025/0345706 A1
(43) Pub. Date: Nov. 13, 2025

(54) ELECTRONIC DEVICE FOR AUTOMATICALLY GENERATING GOLF COURSE AND METHOD THEREOF

(71) Applicants: Jae Heon JUNG, Seoul (KR); Yu Mi LEE, Incheon (KR); SLZ Inc., Siheung-si (KR)

(72) Inventors: Jae Heon JUNG, Seoul (KR); Yu Mi LEE, Incheon (KR)

(73) Assignees: Jae Heon JUNG, Seoul (KR); Yu Mi LEE, Incheon (KR); SLZ Inc., Siheung-si (KR)

(21) Appl. No.: 18/901,101

(22) Filed: Sep. 30, 2024

(30) Foreign Application Priority Data
May 8, 2024 (KR) 10-2024-0060864

(51) Int. Cl. A63F 13/52; A63F 13/812

(52) U.S. Cl. CPC A63F 13/52; A63F 13/812

(57) ABSTRACT

The present disclosure relates to a device for automatically generating a golf course and a method thereof, and according to the present disclosure, based on the source data, components of a first golf course including a tee box, a fairway, and a green can be designed, and a difficulty level of the first golf course to be designed can be calculated based on a distance from the tee box to the hole cup, the outline and path of the first golf course, and the number, area, and position of obstacle factors related to the difficulty level of the first golf course among the components can be determined based on the calculated difficulty level.

### CROSS-REFERENCE TO RELATED APPLICATIONS

A claim for priority under 35 U.S.C. § 119 is made to Korean Patent Application No. 10-2024-0060864 filed on May 8, 2024 in the Korean Intellectual Property Office, the entire contents of which are hereby incorporated by reference.

### BACKGROUND

### 1. Technical Field

The present disclosure relates to a device for automatically generating a golf course and a method thereof.

### 2. Description of Related Art

As the popularity of golf increases day by day, the market size of virtual golf platforms such as screen golf courses is also growing every year.

Unlike sports such as soccer, basketball, and baseball where the place to play is fixed, golf courses are not only different in size but also have varying levels of difficulty due to various obstacle factors included in the golf course.

However, despite the advantages of golf course design, there are not many golf courses applied to the virtual golf platforms.

Particularly, in the case that various people or players are provided with the ability to design and change golf courses themselves, it is expected that the enjoyment and satisfaction will increase significantly, but such technology is not currently available.

### SUMMARY

The embodiment disclosed in the present disclosure is to provide a method and electronic device for automatically generating a golf course.

Furthermore, the embodiment disclosed in the present disclosure is to provide a method and electronic device for designing components a first golf course including a tee box, a fairway, and a green based on source data.

Furthermore, the embodiment disclosed in the present disclosure is to provide a method and electronic device for calculate a difficulty level of a first golf course to be designed based on a distance from the tee box to a hole cup, an outline and path of the first golf course, and determining a number, area, and position of an obstacle factor related to the difficulty level of the first golf course among the components based on the calculated difficulty level.

Technical problems of the inventive concept are not limited to the technical problems mentioned above, and other technical problems not mentioned will be clearly understood by those skilled in the art from the following description.

In an aspect of the present disclosure, a golf course automatic generation device may include a display module; a memory configured to store at least one process to perform a virtual golf course design operation; and a processor configured to perform the operation of the process, wherein the processor may be configured to: display a user interface (hereinafter referred to as ‘UI’) providing a design function of the golf course on the display module, generate a first golf course based on a design function corresponding to a user operation received through the UI, render and output at least one VR content for playing a golf game using the generated first golf course, based on receiving source data for generating the first golf course through the UI, design components of the first golf course including a tee box, a fairway, and a green based on the source data, wherein the source data includes an outline, a path, and an area of the first golf course, determine a number, an area, and a position of each component included in the first golf course according to the area of the first golf course and a type of the component, calculate a difficulty level of the first golf course to be designed based on a distance from the tee box to a hole cup, an outline and path of the first golf course, and determine a number, area, and position of an obstacle factor related to the difficulty level of the first golf course among the components based on the calculated difficulty level.

Furthermore, in another aspect of the present disclosure, a golf course automatic generation method may include displaying a user interface (hereinafter referred to as ‘UI’) providing a design function of the golf course on the display module; generating a first golf course based on a design function corresponding to a user operation received through the UI; and rendering and outputting at least one VR content for playing a golf game using the generated first golf course, wherein generating the first golf course may include: based on receiving source data for generating the first golf course through the UI, designing components of the first golf course including a tee box, a fairway, and a green based on the source data, wherein the source data includes an outline, a path, and an area of the first golf course; determining a number, an area, and a position of each component included in the first golf course according to the area of the first golf course and a type of the component; calculating a difficulty level of the first golf course to be designed based on a distance from the tee box to a hole cup, an outline and path of the first golf course; and determining a number, area, and position of an obstacle factor related to the difficulty level of the first golf course among the components based on the calculated difficulty level.

In addition, a computer program stored in a computer-readable recording medium may be further provided to perform a method for monitoring ultrasound image by being combined with a computer as hardware.

In addition, a computer-readable recording medium recording a computer program for executing a method for implementing the present disclosure may be further provided.

### BRIEF DESCRIPTION OF THE FIGURES

FIG. 1 is a schematic diagram of a golf course automatic generation system according to an embodiment of the present disclosure.

FIG. 2 is a block diagram of the golf course automatic generation device according to an embodiment of the present disclosure.

FIG. 3 is a diagram illustrating playing a golf game using the generated golf course.

FIGS. 4 and 5 are flowcharts of a method for automatically generating a golf course according to the first embodiment of the present disclosure.

FIG. 6 is a diagram illustrating automatic generation of a golf course using a terminal device.

FIGS. 7A to 10 are diagrams illustrating an operation of a UI for generating a golf course according to the first embodiment of the present disclosure.

FIGS. 11 and 12 are flowcharts of a method for automatically generating a golf course according to a second embodiment of the present disclosure.

FIGS. 13 to 19 are diagrams illustrating an operation of a UI for generating a golf course according to a second embodiment of the present disclosure.

### DETAILED DESCRIPTION

In the drawings, the same reference numeral refers to the same element. This disclosure does not describe all elements of embodiments, and general contents in the technical field to which the present disclosure belongs or repeated contents of the embodiments will be omitted. The terms, such as “unit, module, member, and block” may be embodied as hardware or software, and a plurality of “units, modules, members, and blocks” may be implemented as one element, or a unit, a module, a member, or a block may include a plurality of elements.

Throughout this specification, when a part is referred to as being “connected” to another part, this includes “direct connection” and “indirect connection”, and the indirect connection may include connection via a wireless communication network. Furthermore, when a certain part “includes” a certain element, other elements are not excluded unless explicitly described otherwise, and other elements may in fact be included.

Furthermore, when a certain part “includes” a certain element, other elements are not excluded unless explicitly described otherwise, and other elements may in fact be included.

In the entire specification of the present disclosure, when any member is located “on” another member, this includes a case in which still another member is present between both members as well as a case in which one member is in contact with another member.

The terms “first,” “second,” and the like are just to distinguish an element from any other element, and elements are not limited by the terms.

The singular form of the elements may be understood into the plural form unless otherwise specifically stated in the context.

Identification codes in each operation are used not for describing the order of the operations but for convenience of description, and the operations may be implemented differently from the order described unless there is a specific order explicitly described in the context.

Hereinafter, operation principles and embodiments of the present disclosure will be described with reference to the accompanying drawings.

The “electronic device for automatically generating a golf course” according to the present disclosure in this specification includes various devices that may perform computational processing and provide results to a user. For example, the electronic device for automatically generating a golf course according to the present disclosure may include a computer, a server device, and a portable terminal, or may be in the form of one of them.

Here, the computer may include, for example, a notebook, a desktop, a laptop, a tablet PC, a slate PC, and the like mounted with a web browser.

The server device is a server that communicates with an external device to process information, and may include an application server, a computing server, a database server, a file server, a mail server, a proxy server, and a web server.

The portable terminal is a wireless communication device that ensures portability and mobility, and may include all kinds of handheld-based wireless communication devices such as PCS (Personal Communication System), GSM (Global System for Mobile communications), PDC (Personal Digital Cellular), PHS (Personal Handyphone System), PDA (Personal Digital Assistant), IMT (International Mobile Telecommunication)-2000, CDMA (Code Division Multiple Access)-2000, W-CDMA (W-Code Division Multiple Access), WiBro (Wireless Broadband Internet) terminal, a smart phone, and the like, and a wearable device such as at least one of a watch, a ring, bracelets, anklets, a necklace, glasses, contact lenses, or a head-mounted device (HMD).

The function related to artificial intelligence according to the present disclosure operates through a processor and a memory. The processor may be composed of one or more processors. At this time, the one or more processors may be a general-purpose processor such as a CPU, an AP, a DSP (Digital Signal Processor), a graphics-only processor such as a GPU, a VPU (Vision Processing Unit), or an artificial intelligence-only processor such as an NPU. The one or more processors control input data to be processed according to a predefined operation rule or artificial intelligence model stored in the memory. Alternatively, in the case that the one or more processors are artificial intelligence-only processors, the artificial intelligence-only processor may be designed as a hardware structure specialized for processing a specific artificial intelligence model.

The predefined operation rule or artificial intelligence model may be created through learning. Here, being created through learning means that a basic artificial intelligence model is learned by using a plurality of learning data by a learning algorithm, thereby creating a predefined operation rule or artificial intelligence model set to perform a desired characteristic (or, purpose). Such learning may be performed on the device itself in which the artificial intelligence according to the present disclosure is performed, or may be performed through a separate server and/or system. Examples of learning algorithms include supervised learning, unsupervised learning, semi-supervised learning, or reinforcement learning, but are not limited to the examples described above.

The artificial intelligence model may include a plurality of neural network layers. Each of the plurality of neural network layers has a plurality of weights, and performs neural network operations through operations between the operation results of the previous layer and the plurality of weights. The plurality of weights of the plurality of neural network layers may be optimized by the learning results of the artificial intelligence model. For example, the plurality of weights may be updated so that the loss value or cost value acquired by the artificial intelligence model is reduced or minimized during the learning process. The artificial neural network may include a deep neural network (DNN), for example, a convolutional neural network (CNN), a deep neural network (DNN), a recurrent neural network (RNN), a restricted Boltzmann machine (RBM), a deep belief network (DBN), a bidirectional recurrent deep neural network (BRDNN), or a deep Q-network, but is not limited to the examples described above.

According to an exemplary embodiment of the present disclosure, the processor may implement artificial intelligence. Artificial intelligence refers to a machine learning method based on an artificial neural network that mimics human biological neurons to allow a machine to learn. The methodology of artificial intelligence can be divided into supervised learning, where input data and output data are provided together as training data according to the learning method, so that the solution (output data) to the problem (input data) is determined, unsupervised learning, where only input data is provided without output data, so that the solution (output data) to the problem (input data) is not determined, and reinforcement learning, where a reward is given from the external environment whenever an action is taken in the current state, and learning is performed in the direction of maximizing this reward. In addition, the methodology of artificial intelligence may be divided according to the architecture, which is the structure of the learning model. The architecture of widely used deep learning technology may be divided into convolutional neural networks, recurrent neural networks, transformers, and generative adversarial neural networks.

The present device may include an artificial intelligence model. The artificial intelligence model may be one artificial intelligence model, or may be implemented as multiple artificial intelligence models. The artificial intelligence model may be composed of a neural network (or artificial neural network) and may include a statistical learning algorithm that imitates the nerves of biology in machine learning and cognitive science. A neural network may mean a model in general that has problem-solving capabilities by changing the strength of the synapse bond through learning, with artificial neurons (nodes) forming a network by combining synapses. The neurons of the neural network may include a combination of weights or biases. The neural network may include one or more layers composed of one or more neurons or nodes. For example, the device may include an input layer, a hidden layer, and an output layer. The neural network constituting the device may infer a desired result from an arbitrary input by changing the weights of the neurons through learning.

The processor may generate a neural network, train (or learn) a neural network, perform a calculation based on received input data, generate an information signal based on the result of the calculation, or retrain the neural network. The models of the neural network may include various types of models such as CNN, R-CNN, RPN, RNN, S-DNN, S-SDNN, Deconvolution Network, DBN, RBM, Fully Convolutional Network, LSTM Network, Classification Network, and the like, such as GoogleNet, AlexNet, VGG Network, but are not limited thereto. The processor may include one or more processors for performing calculations according to the models of the neural network. For example, the neural network may include a deep neural network.

The neural network may include CNN, RNN, percept, multilayer perceptron, FF (Feed Forward), RBF (Radial Basis Network), DFF (Deep Feed Forward), LSTM (Long Short Term Memory), Gated Recurrent Unit (GRU), Auto Encoder (AE), Variational Auto Encoder (VAE), Denoising Auto Encoder (DAE), Sparse Auto Encoder (SAE), Markov Chain (MC), Hopfield Network (HN), Boltzmann Machine (BM), Restricted Boltzmann Machine (RBM), Depp Belief Network (DBN), Deep Convolutional Network (DCN), Deconvolutional Network (DN), Deep Convolutional Inverse Graphics Network (DCIGN), Generative Adversarial Network (GAN), Liquid State Machine (LSM), Extreme Learning Machine (ELM), Echo State Network (ESN), Deep Residual Network (DRN), Differentiable Neural Computer (DNC), Neural Turning Machine (NTM), Capsule Network (CN), Kohonen Network (KN), and Attention Network (AN), but not limited thereto, and it will be understood by those skilled in the art that any neural network may be included.

According to an exemplary embodiment of the present disclosure, the processor may use various artificial intelligence structures and algorithms such as CNN (Convolution Neural Network), R-CNN (Region with Convolution Neural Network), RPN (Region Proposal Network), RNN (Recurrent Neural Network), S-DNN (Stacking-based deep Neural Network), S-SDNN (State-Space Dynamic Neural Network), Deconvolution Network, DBN (Deep Belief Network), RBM (Restricted Boltzmann Machine), Fully Convolutional Network, LSTM (Long Short-Term Memory) Network, Classification Network, Generative Modeling, eXplainable AI, Continual AI, Representation Learning, and AI for Material Design such as GoogleNet, AlexNet, VGG Network, BERT, SP-BERT, MRC/QA, Text Analysis, Dialog System, GPT-3, and GPT-4 for natural language processing, Visual Analytics, Visual Understanding, Video Synthesis for vision processing, Anomaly Detection, Prediction, Time-Series Forecasting, Optimization, and Recommendation for algorithms ResNet for data intelligence, but not limited thereto. Hereinafter, embodiments of the present disclosure will be described in detail with reference to the attached drawings.

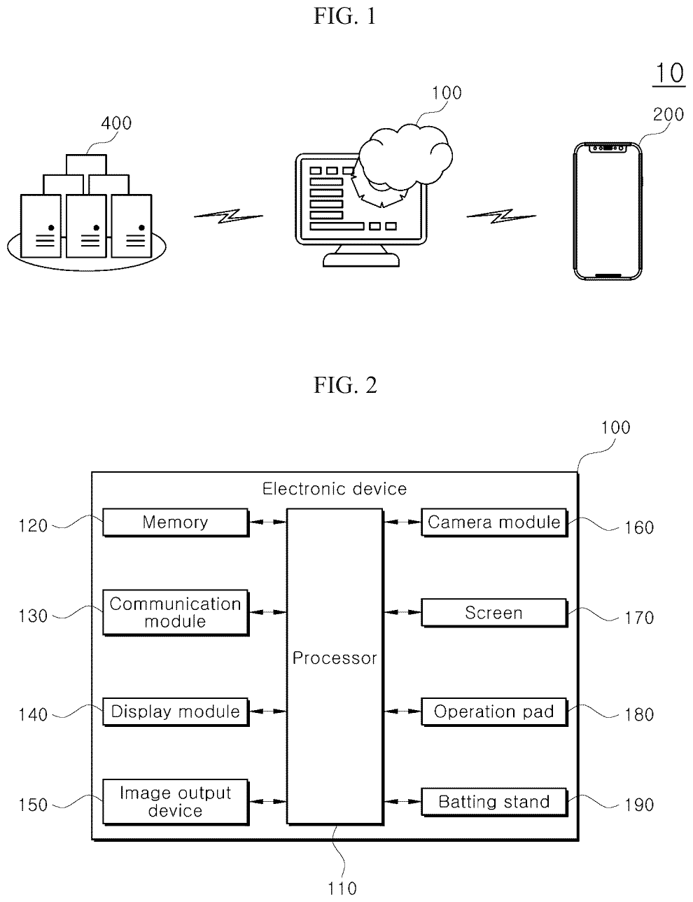

FIG. 1 is a schematic diagram of a golf course automatic generation system 10 according to an embodiment of the present disclosure.

Referring to FIG. 1, a golf course automatic generation system 10 according to an embodiment of the present disclosure includes a golf course automatic generation device 100, a terminal 200, and an external server 400.

However, in some embodiments, the golf course automatic generation system 10 may include fewer or more components than the components illustrated in FIG. 1.

The golf course automatic generation device 100 may generate a golf course that may be used in a game venue such as a screen golf course, or may generate a golf course that is actually intended to be constructed.

The golf course automatic generation device 100 may be configured in the same form as the terminal 200.

The golf course automatic generation device 100 may be configured to include a server device, and may provide a golf course automatic generation service to the terminal 200 connected to the server or an external device.

In addition, the golf course automatic generation device 100 may connect to an external server 400 to receive map data for generating a golf course, receive weather information, or collect various information such as market prices for various components for estimation.

In addition, the golf course automatic generation device 100 may provide the generated golf course to the server 400 of a screen golf course or the server 400 that provides a screen golf service.

Furthermore, the golf course automatic generation device 100 may generate the generated golf course as BIM design data and provide this to the server 400 of a company that constructs a golf course.

Hereinafter, with reference to other drawings, the golf course automatic generation system 10, the device 100, the server, the method, and the program will be described in more detail.

FIG. 2 is a block diagram of the golf course automatic generation device 100 according to an embodiment of the present disclosure.

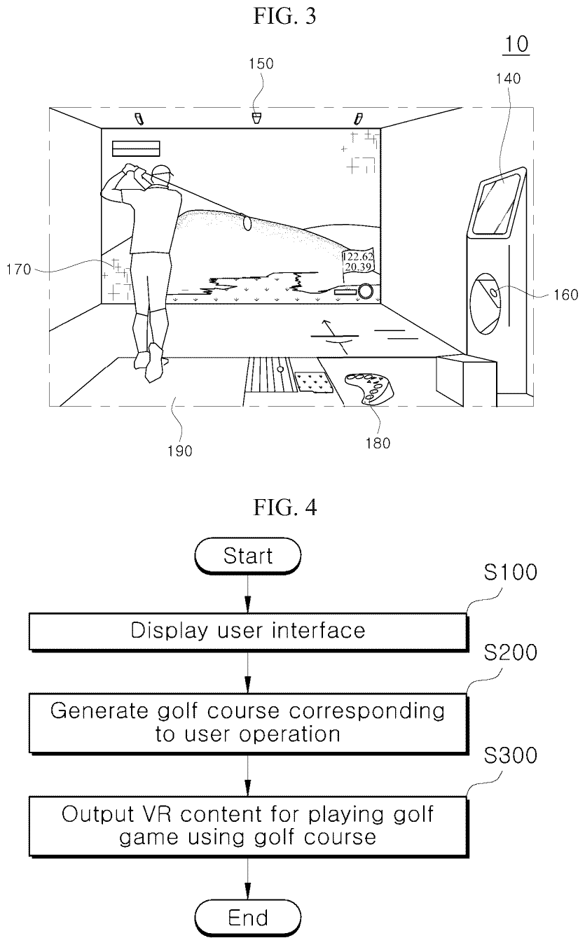

FIG. 3 is a diagram illustrating playing a golf game using the generated golf course.

Referring to FIGS. 2 and 3, the golf course automatic generation device 100 according to an embodiment of the present disclosure includes a processor 110, a memory 120, a communication module 130, a display module 140, an image output device 150, a camera module 160, a screen 170, an operation pad 180, and a batting stand 190.

However, in some embodiments, the automatic golf course generation device 100 may include fewer or more components than the components illustrated in FIGS. 2 and 3.

For example, the golf course automatic generation device 100 may be configured to include a server device, and may include only the processor 110, the memory 120, and the communication module 130, and may communicate with the external server 400 of the screen golf course 170 to provide the golf course automatic generation service. In the embodiment, a user may input various control signals through a user interface displayed through the display module 140 of the terminal 200 installed in the screen golf course 170.

For example, the golf course automatic generation device 100 may be configured to include the terminal 200 device, and include only the processor 110, the memory 120, the communication module 130, and the display module 140, and may provide the golf course automatic generation service by communicating with the external server 400 of the screen golf course 170. In the embodiment, a user may input various control signals through a user interface displayed through the display module 140 of the terminal 200.

The processor 110 may be implemented as the memory 120 that stores data for an algorithm for controlling the operation of components within the device or a program that reproduces the algorithm, and at least one processor 110 that performs the above-described operation using the data stored in the memory 120. At this time, the memory 120 and the processor 110 may be implemented as separate chips. Alternatively, the memory 120 and the processor 110 may be implemented as a single chip.

In addition, the processor 110 may control one or a combination of the components described above to implement various embodiments according to the present disclosure described in the drawings below on the device.

In addition to the operation related to the application program, the processor 110 may typically control the overall operation of the device. The processor 110 may process signals, data, information, and the like which are input or output through the components described above, or may provide or process appropriate information or functions to the user by operating the application program stored in the memory 120.

Furthermore, the processor 110 may control at least some of the components of the device to operate the application program stored in the memory 120. In addition, the processor 110 may operate at least two or more of the components included in the device in combination with each other to operate the application program.

The processor 110 may be implemented as one or more. Hereinafter, even in the case that the processor 110 is expressed singularly, the processor 110 may be considered plural. The processor 110 may control the operation of the components of the golf course automatic generation device 100. The processor 110 may mean a data processing device built into hardware that has a physically structured circuit to perform a function expressed by a code or command included in the program. In this way, the processor 110, as an example of the data processing device built into hardware, may include processing devices such as a microprocessor, a central processing unit (CPU), a processor 110 core, a multiprocessor, an application-specific integrated circuit (ASIC), and a field programmable gate array (FPGA), but the scope of the present disclosure is not limited thereto. The processor 110 may separately have a learning processor for performing artificial intelligence operations, or may have a learning processor on its own.

In various embodiments, the processor 110 may include one or more of a central processing unit (CPU), an application processor (AP), or a communication processor (CP). At least a part of the processor 110 may be hardware, access the memory 120, and perform functions related to instructions stored in the memory 120.

The communication module 130 may include one or more modules that connect the golf course automatic generation device 100 to one or more networks.

The communication module 130 may include one or more components that enable communication with an external device, and may include at least one of a broadcast reception module, a wired communication module, a wireless communication module, a short-range communication module, or a position information module, for example.

The wired communication module may include various wired communication modules such as a Local Area Network (LAN) module, a Wide Area Network (WAN) module, or a Value Added Network (VAN) module, as well as various cable communication modules such as a Universal Serial Bus (USB), a High Definition Multimedia Interface (HDMI), a Digital Visual Interface (DVI), RS-232 (recommended standard 232), a power line communication, or a plain old telephone service (POTS).

The wireless communication module may include a wireless communication module that supports various wireless communication schemes such as a Wi-Fi module, a WiBro Wireless broadband module, Global System for Mobile Communication (GSM), Code Division Multiple Access (CDMA), Wideband Code Division Multiple Access (WCDMA), Universal Mobile Telecommunications System (UMTS), Time Division Multiple Access (TDMA), Long Term Evolution (LTE), 4G, 5G, and 6G.

The wireless communication module may include a wireless communication interface including an antenna and a transmitter that transmit a communication signal. In addition, the wireless communication module may further include a signal conversion module that modulates a digital control signal output from the processor 110 through the wireless communication interface into an analog wireless signal under the control of the processor 110.

The short-range communication module is for short-range communication, and may support short-range communication by using at least one of Bluetooth (Bluetooth™), Radio Frequency Identification (RFID), Infrared Data Association (IrDA), Ultra-Wideband (UWB), ZigBee, Near Field Communication (NFC), Wireless-Fidelity (Wi-Fi), Wi-Fi Direct, and Wireless Universal Serial Bus (Wireless USB) technologies.

The communication module 130 may also use the name of a communication interface.

The communication interface may establish communication between an electronic device and an external device. For example, the communication interface may communicate with the external device through wireless communication, for example, Wireless Fidelity (Wi-Fi), Bluetooth, Near Field Communication (NFC), magnetic stripe transmission (MST), and the like or wired communication.

The display module 140 displays (outputs) information processed by the device. For example, the display unit may display execution screen information of an application program (e.g., an application) running on the device, or User Interface (UI) and Graphical User Interface (GUI) information according to such execution screen information.

The display module 140 may display various contents (e.g., a text, an image, a video, an icon, a symbol, etc.). For example, the display may display an image corresponding to at least one image data included in the application program. In various embodiments, in the case that the electronic device adopts a VR mode, the display may separate one image into two images corresponding to the user's left and right eyes. In various embodiments, the display may include a liquid crystal display (LCD), a light-emitting diode (LED) display, an organic light-emitting diode (OLED) display, a microelectromechanical systems (MEMS) display, or an electronic paper display.

The memory 120 may store data supporting various functions of the device. The memory 120 may store a plurality of application programs or applications run on the device, data for the operation of the device, and commands. At least some of these application programs may exist for the basic function of the device. Meanwhile, the application program may be stored in the memory 120, installed in the device, and driven to perform operations or functions by the processor 110.

The memory 120 may store data supporting various functions of the device, a program for the operation of the processor 110, input/output data (e.g., a music file, a still image, a video image, etc.), and a plurality of application programs or applications run on the device, data for the operation of the device, and commands. At least some of these application programs may be downloaded from the external server 400 via wireless communication.

The memory 120 may include at least one type of storage medium including a flash memory type, a hard disk type, an SSD (Solid State Disk) type, an SDD (Silicon Disk Drive) type, a multimedia card micro type, a card type memory (e.g., an SD or XD memory), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disk. In addition, the memory 120 may be a database that is separate from the device but connected by wire or wirelessly.

The memory 120 may be electrically connected to the processor 110 and may store at least one code executed in the processor 110. The memory 120 may collectively refer to various types of storage devices. The memory 120 may store information necessary for performing operations using artificial intelligence, machine learning, and artificial neural network.

The memory 120 may store various learning models. The learning models stored in the memory 120 may infer a result value for new input data that is not learning data, and the inferred value may be used as a basis for judgment for performing a certain operation. The learning models stored in the memory 120 may perform learning based on label information, and various backpropagation algorithms may be applied so that the loss function has a target value to increase the accuracy of learning.

In addition, the memory 120 may have multiple processes for the golf course automatic generation device 100.

The image output device 150 refers to a device such as a beam projector that projects an image on a screen using light, and may be installed in a screen golf course 170 as shown in FIG. 3.

The camera module 160 may include at least one camera, and may be installed in the screen golf course 170 to capture a user's hitting posture and a golf ball hit by the user.

The camera module 160 processes image frames such as still images or moving images obtained by an image sensor in a shooting mode. The processed image frames may be displayed on the display unit or stored in the memory 120.

The camera module 160 may capture a still image and a video image. For example, when an electronic device is mounted on an HMD device, the camera module 160 may capture images of at least a front area of the HMD device. In one embodiment, the camera module 160 may be activated after a specified time has elapsed since the electronic device is mounted on the HMD device and the HMD device is started to operate. In various embodiments, the camera module 160 may be activated from the time the electronic device is mounted on the HMD device. Alternatively, the camera module 160 may be activated from the time the user puts on the HMD device.

In various embodiments, the camera module 160 may include, for example, at least one depth camera (e.g., a Time of Flight (TOF) type or a structured light type and a color camera (e.g., an RGB camera). In addition, the camera module 160 may further include at least one sensor (e.g., a proximity sensor), a light source (e.g., an LED array), or the like in relation to performing a function. In various embodiments, the at least one sensor may be configured as a separate module from the camera module 160 and may perform sensing of at least the front area of the HMD device. For example, the sensor module (e.g., proximity sensor) may perform sensing of an object by emitting infrared light (or transmitting ultrasonic wave) to the front area of the HMD device and receiving infrared light (or receiving ultrasonic wave) reflected from the object. In this case, the camera module 160 may be activated from the time at which at least one object is sensed by the sensor module.

The processor 110 may perform calculation or data processing related to control and communication of at least one other component of the electronic device. For example, the processor 110 may receive captured image data from the camera module 160 and detect an object existing within the shooting range of the camera module 160 based on the captured image data.

In one embodiment, the processor 110 may calculate or detect the quantity of at least one detected object, the size of the objects, the distance between the objects and the HMD device (or the user wearing the HMD device), and the movement of the objects. The processor 110 may control the operation of the display based on the calculated or detected information.

The operating pad 180 is installed near the batting stand 190 where the golf user stands, and may control various means provided on the batting stand 190, such as operating a tee shot or adjusting the position of the tee shot.

The batting stand 190 is installed at the position where the golf user stands, and may be the batting stand 190 whose angle may be adjusted according to the screen golf course 170.

In addition, the golf course automatic generation device 100 may further include the following components.

The input unit is for inputting image information or signal, audio information or signal, data, or information input from a user, and may include at least one camera, at least one microphone, and at least one user input unit. Voice data or image data collected by the input unit may be analyzed and processed as a user control command.

The input unit is for receiving information from a user, and when information is input through the input unit, the processor 110 may control the operation of the device to correspond to the input information. The input unit may include a hardware physical key (e.g., a button located on at least one of the front, rear, and side of the device, a dome switch, a jog wheel, a jog switch, etc.) and a software touch key. As an example, the touch key may be formed as a virtual key, a soft key, or a visual key displayed on a display unit of a touch screen type through software processing, or may be formed as a touch key placed on a part other than the touch screen. Meanwhile, the virtual key or visual key may have various forms and be displayed on the touch screen, and may be formed as, for example, a graphic, a text, an icon, a video, or a combination thereof.

The sensor unit senses at least one of the internal information of the device, the surrounding environment information surrounding the device, and the user information, and generates a sensing signal corresponding thereto. The processor 110 may control the operation or operation of the device based on the sensing signal, or perform data processing, a function, or an operation related to an application program installed on the device.

As described above, the sensor unit may include at least one of a proximity sensor, an illumination sensor, a touch sensor, an acceleration sensor, a magnetic sensor, a G-sensor, a gyroscope sensor, a motion sensor, an RGB sensor, an infrared sensor IR sensor, a finger scan sensor, an ultrasonic sensor, an optical sensor (e.g., a camera), a microphone, an environmental sensor (e.g., at least one of a barometer, a hygrometer, a thermometer, a radiation detection sensor, a heat detection sensor, and a gas detection sensor), or a chemical sensor (e.g., a healthcare sensor, a biometric recognition sensor, etc.). Meanwhile, the device may utilize information sensed by at least two or more of these sensors in combination.

The output part is for generating output related to visual, auditory or tactile sensations, and may include at least one of a display part, an audio output part, a haptic module, and an optical output part. The display part may be formed as a touch sensor and a mutual layer structure or formed as an integral part, thereby implementing a touch screen. The touch screen may function as a user input part that provides an input interface between the device and a user, and may provide an output interface between the device and the user.

The audio output part may output audio data received through the communication module 130 or stored in the memory 120, or output an audio signal related to a function performed by the device. The audio output part may include a receiver, a speaker, a buzzer, and the like.

The interface part performs as a passageway for various types of external devices connected to the device. The interface unit may include at least one of a wired/wireless headset port, an external charger port, a wired/wireless data port, a memory card port, a port for connecting a device equipped with an identification module (SIM), an audio I/O (Input/Output) port, a video I/O (Input/Output) port, and an earphone port. In the present device, appropriate control related to the external device connected to the interface unit may be performed.

The input/output interface may serve as an interface that may transmit commands or data input from a user or other external device to other components of the electronic device. In addition, the input/output interface may output commands or data received from the other components of the electronic device to the user or other external device.

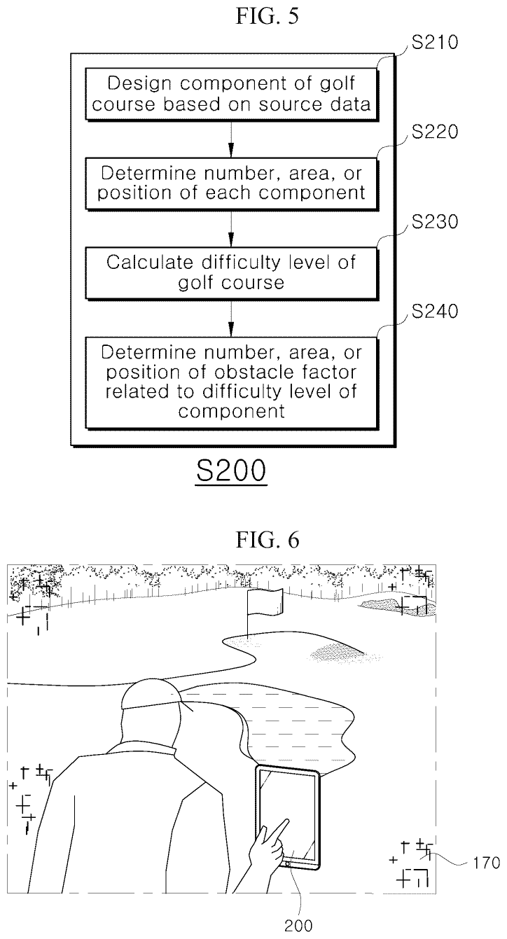

FIGS. 4 and 5 are flowcharts of a method for automatically generating a golf course according to the first embodiment of the present disclosure.

FIG. 6 is a diagram illustrating automatic generation of a golf course using a terminal device.

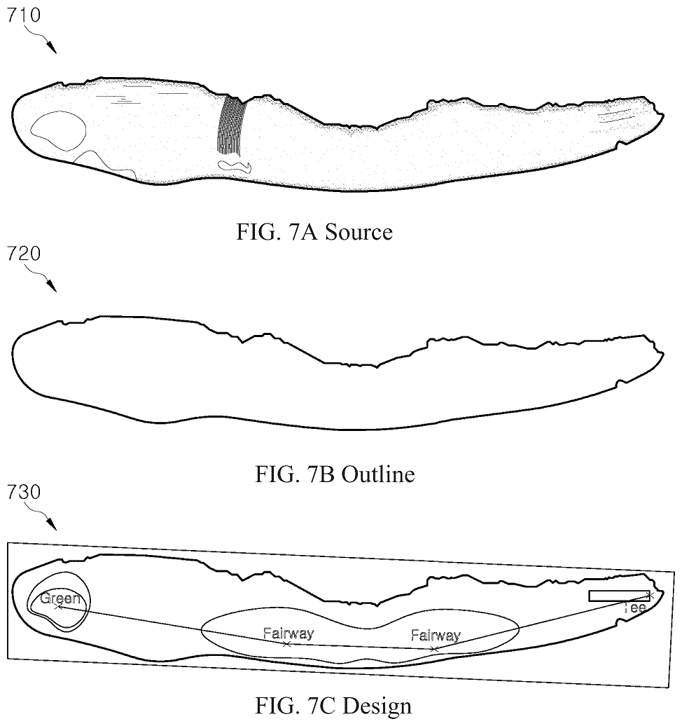

FIGS. 7A to 10 are diagrams illustrating an operation of a UI for generating a golf course according to the first embodiment of the present disclosure.

Referring to FIG. 4 to FIG. 10, a detailed description will be given of the golf course automatic generation system 10, the device, the server, and the method according to the first embodiment of the present disclosure.

The processor 110 displays a user interface (hereinafter, referred to as “UI”) providing a golf course design function on the display module 140 (step S100).

The processor 110 generates a first golf course based on a design function corresponding to a user operation received through the UI (step S200).

The processor 110 renders and outputs a VR content for playing a golf game using the golf course generated in step S200 (step S300).

The processor 110 may provide a golf course design service to the user by displaying the user interface of the golf course design program through the display module 140.

The user may input various values for designing the golf course through the user interface displayed on the display module 140, and through this, may check the golf course being designed and proceed with additional design or modify the golf course.

Referring to FIG. 5, step S200, which is a step of generating the golf course, may further include steps S210, S220, S230, and S240.

When the processor 110 receives source data for generating the first golf course through the UI, the processor 110 designs components of the first golf course including at least one of a tee box, a fairway, or a green based on the source data (step S210).

At this time, the source data may include at least one of an outline, a path, or an area of the first golf course.

Referring to FIGS. 7A to 7C, the source data is exemplified and may include source data 710 including the terrain of the golf course, outline data 720, and design data 730 indicating the path or direction of the golf course by indicating an approximate green, tee shot, and fairway.

The processor 110 determines at least one of the number, the area, or position of each component that may be included in the first golf course according to the area of the first golf course and the type of the component (step S220).

The processor 110 calculates the difficulty level of the first golf course to be designed based on the distance from the tee box to the hole cup, the outline and the path of the first golf course (step S230).

The processor 110 determines at least one of the number, the area, or the position of an obstacle factor related to the difficulty level of the first golf course among the components based on the difficulty level calculated in step S230 (step S240).

In the embodiment of the present disclosure, the components included in the golf course include a teeing ground, a tee box, a fairway, a hazard, a bunker, an apron, a green, an out of bounds (OB: Out of Bounds), and the like.

Any component related to the difficulty level of playing golf among these components may be set as the obstacle factor.

For example, the processor 110 may increase the difficulty level of the corresponding golf course by increasing the area of the hazard.

For example, the processor 110 may increase the difficulty level of the corresponding golf course by arranging the hazard on the path that a golf ball needs to travel from a tee box to a hole cup, and may further increase the difficulty level of the corresponding golf course by increasing the size of the arranged hazard.

The processor 110 may generate a path range that a golf ball needs to travel from a tee box to a hole cup of the first golf course, and may calculate a difficulty level index according to the arrangement of the obstacle factor of the first golf course based on the arrangement relationship with the path range of obstacle factor related to the difficulty level of the first golf course.

For example, in the case that the obstacle factor related to the difficulty level of the first golf course is arranged on the path range, the processor 110 may calculate the difficulty level index according to the obstacle factor arrangement of the first golf course as the highest score.

In contrast, in the case that the obstacle factor related to the difficulty level of the first golf course is not arranged on the path range, the processor 110 may calculate the difficulty level index according to the distance between the corresponding obstacle factor and the path range, and the difficulty level index may decrease as the corresponding obstacle factor is farther from the path range.

In addition, the processor 110 may adjust the difficulty level of the corresponding golf course by expanding or narrowing the area of the green in addition to direct obstacle factor such as a hazard and a bunker.

Depending on the type, the obstacle factor may further include an escape difficulty level.

The processor 110 may set the escape difficulty level so that the obstacle factor is designed in the case that the user has a golf skill level higher than a preset level.

In one embodiment, the processor 110 may set the difficulty level of the first golf course by adjusting the ratio of fairway and rough in the first golf course.

Once the processor 110 receives the source data for generating the first golf course, the processor 110 may design representative components of the first golf course including a tee box, a fairway, and a green based on the received source data.

In addition, the source data may include at least one of an outline, a path, or an area for the golf course, but is not limited thereto.

When the processor 110 receives the outline, path, and area for generating the first golf course, the processor 110 calculates the difficulty level of the first golf course to be designed based on the received outline, path, and area.

Specifically, when the processor 110 receives the shape outline, the hitting path, and the area of the golf course, the processor 110 may calculate the first difficulty level of the corresponding golf course based on this.

Then, the processor 110 may display the calculated first difficulty level through the UI, ask the user whether to generate a golf course with the first difficulty level, and receive a response from the user.

The processor 110 may determine the number, the area, or the position of obstacle factor related to the difficulty level of the first golf course among the components based on the calculated first difficulty level or a second difficulty level requested by the user.

The processor 110 may increase the difficulty level of the corresponding golf course by increasing at least one of the number or the area of obstacle factor.

The processor 110 may also increase the difficulty level of the corresponding golf course by arranging the position of the obstacle factor on the path that the golf ball needs to travel or arranging it close to the path.

In one embodiment, the processor 110 may display at least one design option designed according to the determined matter as the user interface, and design a golf course according to the design option selected by the user through the user interface.

For example, in the case that the first difficulty level or the second difficulty level is 75, the processor 110 may design two or more different golf courses corresponding to the difficulty level of 75, and display the two or more designed different golf courses as the user interface to request the user to select.

In one embodiment, the processor 110 may sequentially design components included in a golf course, and may display a design option for designing each component step by step so that the golf course may be sequentially designed for each component.

The processor 110 displays different design option for arranging fairway and rough within an outline according to the first or second difficulty level on the user interface, and stores the design option selected by a user through the user interface.

The processor 110 displays different design options for arranging a hazard and a bunker within an outline according to the first or second difficulty level on the user interface, and stores design options selected by a user through the user interface. At this time, the user may input detailed options for selecting the type of hazard and bunker.

In addition to the design option displayed by the user interface, the processor 110 may also receive a custom option with a modified design option from the user through the user interface.

In the case that the custom option is received through the user interface, the processor 110 calculates a third difficulty level for the first golf course based on the custom option received from the user, and in the case that the difference between the third difficulty level and the first or second difficulty level is outside a preset range, the processor may ask the user whether the user wants to change the difficulty level through the user interface.

At this time, in the case that a response is received from the user through the user interface that the user does not want to change the difficulty level, the processor 110 may modify the custom option so that the difficulty level falls within the difficulty level range of the first or second difficulty level and reflect it in the design option.

In one embodiment, the processor 110 may automatically design a golf course based on the golf skill of a player (user) participating in a golf game.

Specifically, in the case that the golf skill of at least one user participating in the golf game is received through the user interface, the processor 110 may determine the number, the area, and the position of each component set as an obstacle factor based on the golf skill of the corresponding user.

At this time, the golf skill may be include multiple levels (e.g., beginner to expert).

When the level corresponding to the golf skill of each of at least one user participating in the golf game through the user interface is set, the processor 110 may generate a golf course based on the set level.

In one embodiment, the golf skill may include at least one of the user's driving distance, average score, fairway landing rate, green-on success rate, or putting average.

In this way, the golf course may be designed to include multiple sub-items related to the golf skill, and the more detailed information is input, the higher the relevance between the user's golf skill and the golf course.

When the user completes playing the golf game using the first golf course, the processor 110 may modify an obstacle factor setting value for designing the second golf course for the next game based on the play history and the setting value for obstacle factor when designing the first golf course.

In one embodiment, the processor 110 may design the second golf course so that a user with poor performance may improve the user's performance when playing using the first golf course.

Specifically, the processor 110 may evaluate scores for multiple evaluation items based on the play history of the user who participated in the golf game.

In addition, the processor 110 may control the obstacle factor that causes a decrease in the evaluation score among the play history of the user who participated in the golf game to be deleted, of which weight is reduced, or of which position is changed when designing the second golf course.

In the case that there is an item among the evaluation scores for the respective items for the first golf course for the user that is lower than the threshold value compared to the user's golf skills, the processor 110 determines that the design of the obstacle factor related to the item is incorrect, and may modify the obstacle factor setting value of the second golf course to lower the difficulty level of the obstacle factor.

In the case that there is an item among the evaluation scores for the respective items for the first golf course for the user that is higher than a threshold value compared to the user's golf skill, the processor 110 determines that the design of the obstacle factor related to the item is incorrect, and may modify the obstacle factor setting value of the second golf course to raise the difficulty level of the obstacle factor.

In one embodiment, in the case that there are multiple users participating in the golf game, the processor 110 may identify at least one evaluation item among the multiple users that has a low evaluation score for the first golf course compared to the user's golf skill in the first user's play history, and may recommend lowering the golf skill set for the first user based on the identified result.

The processor 110 may control the obstacle factor that causes a decrease in the evaluation score of the identified evaluation item to be deleted, of which weight is reduced, or of which position is changed when the second golf course is designed.

In one embodiment, the processor 110 may identify the user's weak point by referring to the evaluation score for the respective items based on the play history of the first golf course of the user with a relatively low score among multiple users who participated in the golf game, and may control the obstacle factor related to the identified weak point of the user to be deleted, of which weight is reduced, or of which position is changed when the second golf course is designed.

In one embodiment, the processor 110 calculates scores for multiple items related to golf skills based on the play history of each of the multiple users.

The processor 110 may control such that the components related to items determined as weak points of the first user based on the scores of the multiple items calculated above is deleted, of which weight is reduced, or of which position is changed when the second golf course is designed.

In addition, the processor 110 may control such that the weight of the components related to items determined as strong points of the first user based on the scores of the multiple items calculated above is increased when designing the second golf course.

For example, the processor 110 may modify the design value of the component of the second golf course so that the position of the tee box and the position of the hole are adjusted based on the average hitting direction of the first user.

In addition, the processor 110 may modify the design value of the component of the second golf course so that the position of the obstacle factor is adjusted based on the distance and average hitting direction of the first user. Specifically, the processor 110 may predict the position of the golf ball hit by the first user based on the distance and average hitting direction of the first user, and modify the design value of the component of the second golf course so that the obstacle factor is not placed at the predicted position.

In one embodiment, the golf course automatic generation device 100 may design a golf course according to the playable time of a user playing a golf game.

Specifically, in the case that a target play time for a golf game is received through the user interface, the processor 110 may determine the distance from the tee box to the hole and the area of the golf course so that the golf game may be completed within the target play time based on the golf skill of the user participating in the golf game, and determine the difficulty level of each component included in the golf course.

The processor 110 identifies the range of the adjustable inclination of the batting stand 190 for playing the golf game using the first golf course. This means identifying the range of the inclination adjustment of the batting stand 190 of the seat used by the user in the screen golf course 170.

The processor 110 designs the terrain of the first golf course within the identified inclination range, and may control the inclination of the batting stand 190 according to the inclination of the terrain corresponding to the position of the golf ball when the golf game is played using the first golf course.

The golf course automatic generation device 100 according to the embodiment of the present disclosure has the effect of allowing the user to experience the inclination by designing the golf course according to the adjustable inclination range of the batting stand 190 that actually exists.

In one embodiment, the processor 110 may store first tag information of the component related to the play difficulty level of the golf course used in the golf game in the memory 120.

After the play of the golf game is completed, the processor 110 may store second tag information of play history related to the golf skill of the user who participated in the golf game in the memory 120.

More specifically, after the play of the golf game is completed, the processor 110 may calculate the user's scores for multiple items related to the golf skills of the user who participated in the golf game. In addition, the processor 110 may store the user's scores for multiple items related to the golf skill in the memory 120 as the second tag information.

In addition, when designing the golf course for the golf game, the processor 110 may determine the golf skill of each user based on the first tag information and the second tag information for at least one previous golf game by searching the play history of each user who participated in the golf game.

In an additional embodiment, the processor 110 may add a wind speed and a wind direction to the golf course as dynamic obstacle factors.

The obstacle factors may include the dynamic obstacle factors that may be set and changed during the play of the golf game.

In one embodiment, the processor 110 may calculate in real time an evaluation scores for multiple items related to golf skills for each hit of the user according to the progress of the golf game using the first golf course.

In the case that the processor 110 determines that the calculated real time evaluation score is higher than the user's golf skill while the golf game using the first golf course is in progress, the processor 110 may set the dynamic obstacle factor to be activated on the first golf course.

In one embodiment, the processor 110 may calculate a gap between the calculated real time evaluation score and the user's golf skill. Then, the processor may determine the wind speed and the wind direction on the first golf course according to the calculated gap and set the dynamic obstacle factor to be activated.

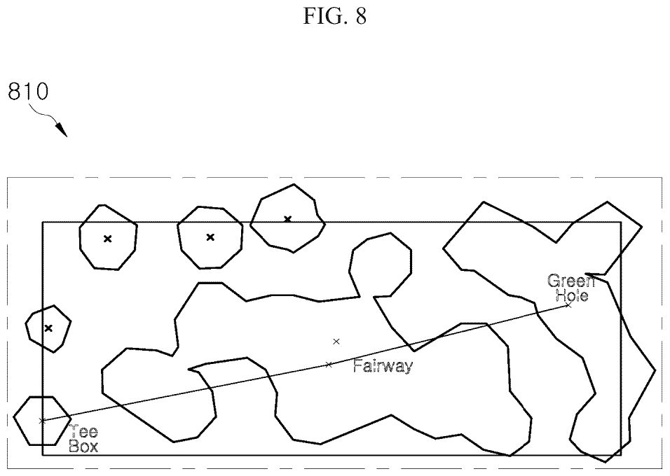

Referring to a two-dimensional design diagram 810 of FIG. 8, the processor 110 may arrange the fairway according to the path from the tee box, the green, and the hole.

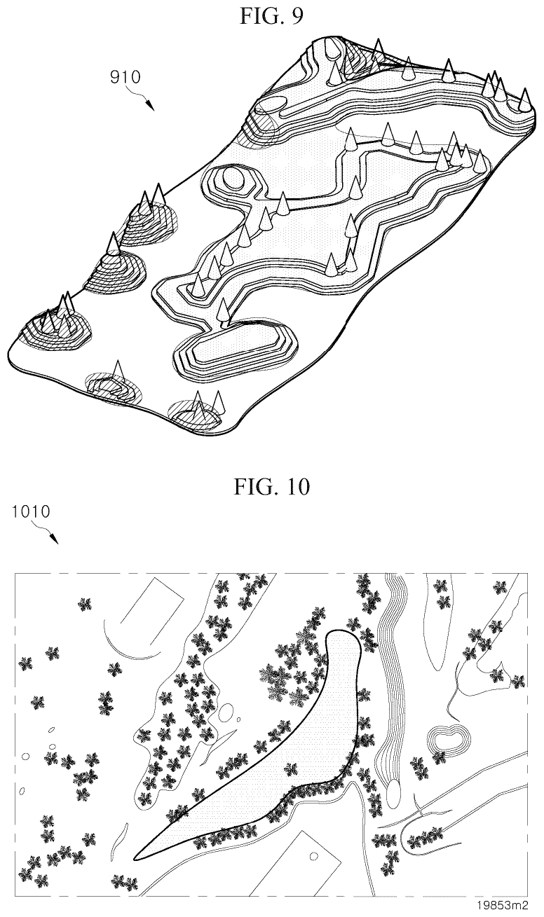

Then, the processor 110 may design a three-dimensional design diagram 910 as in FIG. 9 by referring to the two-dimensional design diagram 810.

As an additional embodiment, referring to FIG. 10, the golf course automatic generation device 100 according to the embodiment of the present disclosure may generate and provide a virtual golf course, but may also provide a mode in which a virtual golf course may be generated based on a specific region that actually exists when the region is selected.

For example, when map data 1010 for a specific region is received, the processor 110 may analyze the map data to generate a golf course. Alternatively, the processor 110 may receive the map data 1010 for a specific region and may proceed with designing a golf course by inputting an outline for the region through the user interface.

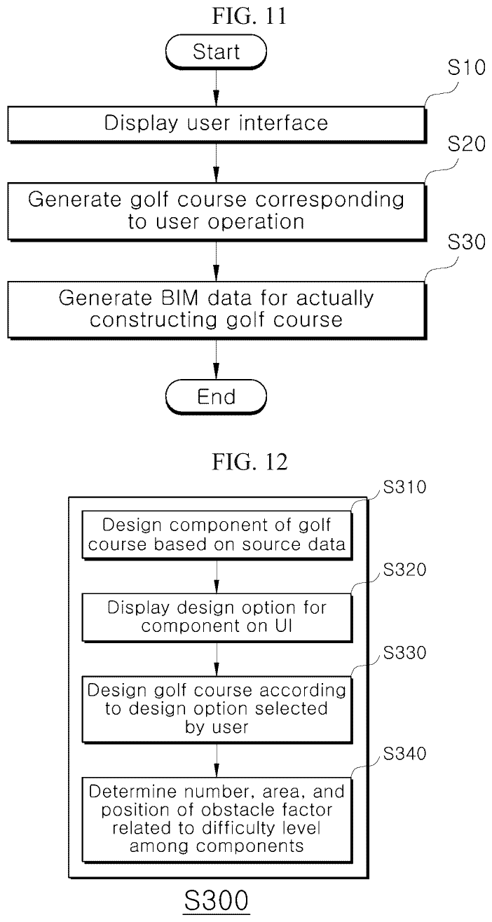

FIGS. 11 and 12 are flowcharts of a method for automatically generating a golf course according to a second embodiment of the present disclosure.

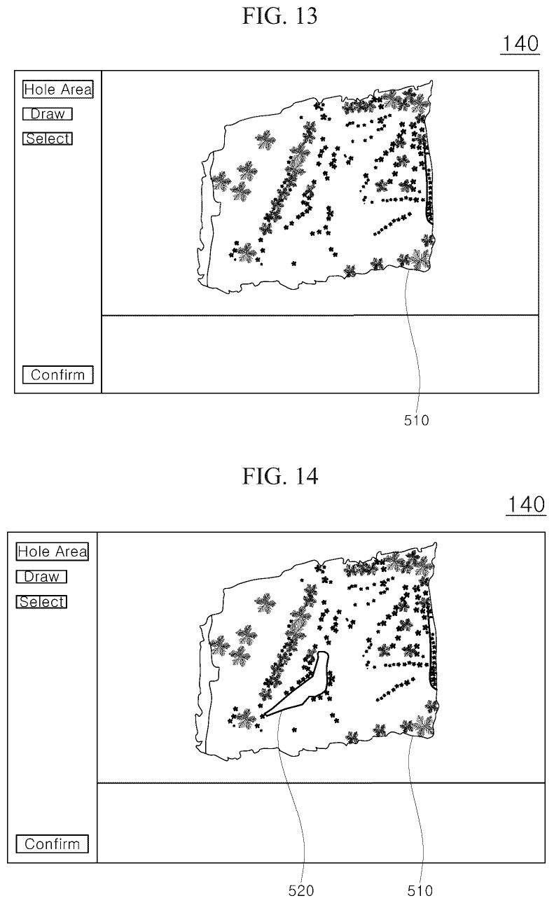

FIGS. 13 to 19 are diagrams illustrating an operation of a UI for generating a golf course according to a second embodiment of the present disclosure.

Hereinafter, the golf course automatic generation system 10, the device, the server, and the method according to the second embodiment of the present disclosure will be described with reference to FIGS. 11 to 19.

The processor 110 displays a user interface (hereinafter referred to as ‘UI’) providing a design function of the golf course on the display module 140 (step S10).

The processor 110 generates a golf course based on the design function corresponding to a user operation received through the UI (step S20).

The processor 110 may provide a golf course design service to the user by displaying a user interface of a golf course design program through the display module 140.

The user may input various values for designing a golf course through the user interface displayed by the display module 140, and through this, may identify the golf course being designed and proceed with additional design or modify the golf course.

Referring to FIG. 12, the step of generating (designing) a golf course may further include steps S21 to S24.

When the source data is received, the processor 110 may design a component of a golf course including at least one of an area of terrain included in the golf course, an outline of the golf course, a tee box, a fairway, or a green based on source data.

The source data may be applied to map data of a specific region.

The map data may be an aerial photograph or satellite photograph of the region. The map data may be applied to data acquired by direct shooting, or may be applied to public data, data from the external server 400, or the like.

When the map data of the specific region is received, the processor 110 may design a component of the golf course including at least one of the outline, the tee box, the fairway, and the green of the golf course based on the map data.

Then, when the processor 110 receives detailed source data for designing each component according to a preset process, the processor 110 displays at least one design option for each component based on the detailed source data in the UI, and may design the golf course according to the design option selected through the UI.

That is, the golf course automatic generation device 100 provides a program that may automatically design a golf course through the UI, and requests that a setting value be input according to a sequential process, and the user inputs the setting value according to the golf course that the user wants to design, and each process is performed, and when all processes are completed, the design of the golf course is completed.

Referring to FIG. 13, the source data including map data 510 is received, and the processor 110 displays the map data 510 with the display module 140.

“Hole Area”, “Draw”, “Select”, and “Confirm” functions are displayed on the left side of the UI displayed as the display module 140 of FIG. 13.

The user may place the hole of the golf course that the user wants to design through the “Hole Area” function. In this case, the processor 110 may design the outline of the golf course based on the position of the hole placed by the user.

The user may display the outline of the golf course that the user wants to design through the “Draw” function, select it through the “Select” function, and complete the selection through the “Confirm” function.

The “Hole Area” placement function and “Draw” function are the user's choice and are not necessary.

Referring to FIG. 14, an outline 520 of a golf course to be designed is displayed in the map data 510 displayed by the display module 140, and the outline 520 may be directly displayed by the user as described above.

In one embodiment, the processor 110 may generate at least one outline for designing a golf course in the map data 510 based on the topographic information of the map data 510.

For example, in the case that the processor 110 determines that one golf course may be designed in the map data 510 as shown in FIG. 14 based on the analysis result of the topographic information of the map data 510, the processor 110 may display one outline 520 as shown in FIG. 14, or in the case that it is determined that multiple golf courses may be designed, the processor 110 may display multiple outlines.

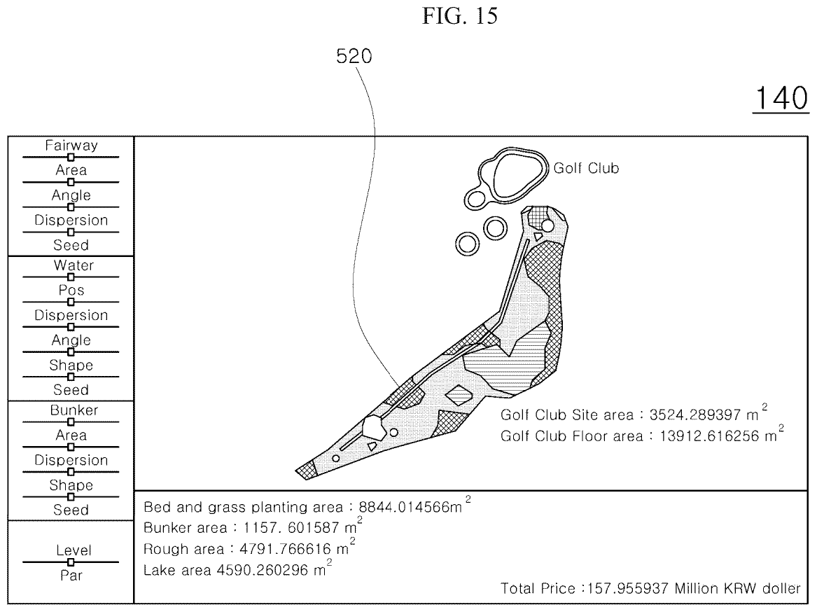

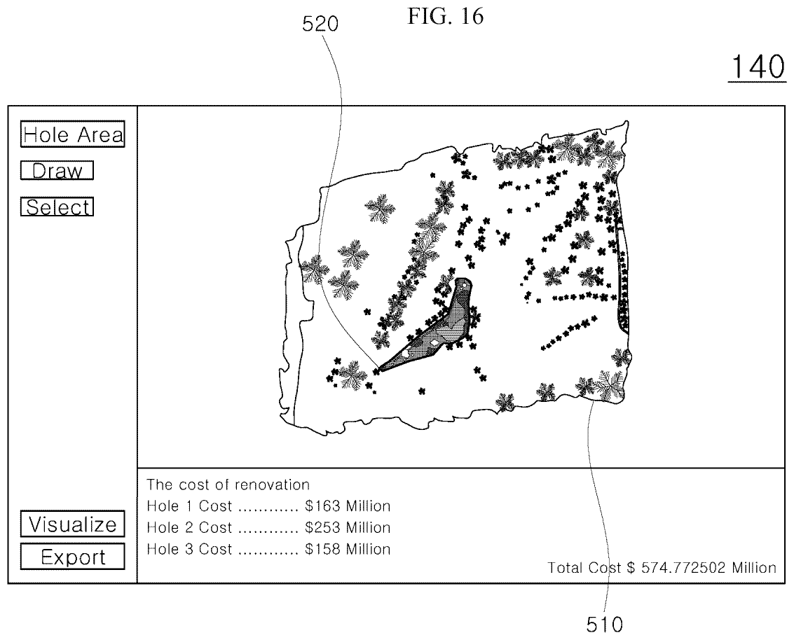

Referring to FIG. 15 and FIG. 16, the processor 110 may display each component of the designed golf course within the outline 520 through the UI displayed by the display module 140, and may display various components as displayed on the left side of the UI, and display the area of the golf course and the area of each component included in the golf course.

In one embodiment, the golf course automatic generation device 100 may automatically design a golf course using an artificial intelligence model learned with learning data built based on map data including an actual golf course (hereinafter, “actual golf course”) and information on each component included in the actual golf course.

That is, when the map data of a region where the user wants to design a golf course is input into the artificial intelligence model, the processor 110 may design an outline of a golf course according to the map data based on the topographic information of the input map data using the artificial intelligence model.

Then, the processor 110 may place at least one component for completing the golf course within the outline using the artificial intelligence model.

At this time, the processor 110 may calculate the difficulty level of the corresponding golf course based on the outline through the artificial intelligence model, and design and place each component appropriately for the calculated difficulty level. In one embodiment, in the case that the difficulty level required for the corresponding golf course is separately requested or received from the user, the processor 110 may design each component within the corresponding golf course based on the requested or received difficulty level.

The artificial intelligence model may be stored in the memory 120 or may be stored in an external cloud server.

In addition, a program for calculating the cost of constructing the golf course may be stored in the memory 120.

The processor 110 may calculate the amount required to actually build the golf course designed through the golf course automatic generation device 100 using a cost calculation program.

In one embodiment, the processor 110 may access the external server 400 through the communication unit to inquire about the land price of a region where a user wants to design a golf course, and calculate the cost required to design each component in the memory 120 or program, thereby calculating the expected amount required in the case that the golf course designed through the golf course automatic generation device 100 is actually built.

In the embodiment of the present disclosure, the detailed source data may include at least one of the number of each component, the area of each component, the planting area, the type of planting, the number of plantings, and the type of soil.

The processor 110 may calculate at least one design option for each component and the construction cost according to each design option based on the detailed source data, and display this on the UI.

The processor 110 may generate at least some of the detailed source data through the results of the analysis of the map data by the artificial intelligence model.

In addition, in order to calculate the construction cost as described above, the memory 120 may store at least one of the construction cost by planting type, the construction cost per planting allowance, and the construction cost by area according to the soil type. In some embodiments, the construction cost may be identified through information disclosed to the external server 400.

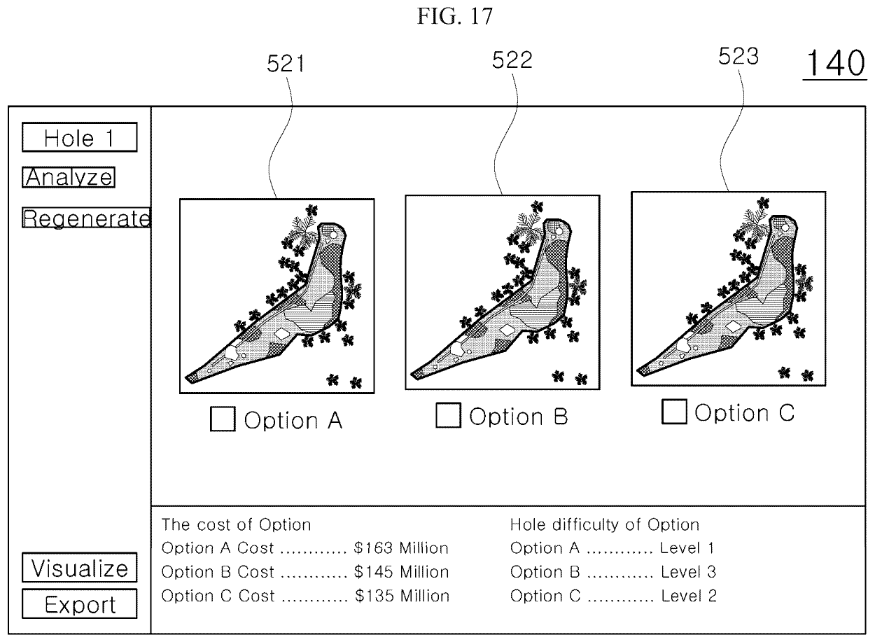

Referring to FIG. 17, the golf course automatic generation device 100 may provide the user with various design options for the golf course.

The processor 110 provides design option A 521, design option B 522, and design option C 523 through the UI, and provides information on the estimated construction cost and difficulty level for each design option.

The user may compare the design cost of each design option displayed through the UI with the user's own budget and check whether the play difficulty level is similar to what the user is intended.

The user may request that the design process proceed by selecting one of the multiple design options provided, or may enter additional request.

In this case, the additional request may be a request to increase or decrease the expected design cost, or a request to increase or decrease the play difficulty level.

In some embodiments, in the case that budget information that may be used for golf course construction is input from the user, the processor 110 may design a golf course based on the input budget information.

In an embodiment of the present disclosure, in the case that a first difficulty level for a golf course is received, the processor 110 may determine the number, the area, or the position of an obstacle factor related to play difficulty level among the component based on the area of terrain included in the golf course, the distance from the tee box to the hole, and the first difficulty level.

In one embodiment, after designing the golf course, the processor 110 may calculate a second difficulty level for each obstacle factor based on the position of the obstacle factor relative to the path from the tee box to the hole of the golf course, the type of the obstacle factor, and the area.

The processor 110 may determine the path information for the golf ball to move from the tee box to the hole after being hit. The path of the golf ball is not limited to a single straight path, but since the starting point tee box and the destination hole are determined, there is generally a range of paths for correct play.

In addition, the more obstacle factors are placed on the range of the path, the higher the difficulty level of the corresponding golf course. Conversely, the farther the obstacle factors are placed from the range of this path, the lower the difficulty level of the corresponding golf course.

That is, the processor 110 generates the path range of the golf ball from the tee box to the hole based on the outline, the tee box, and the hole of the golf course.

In addition, the processor 110 may determine the placement position and the placement area of the obstacle factors based on the path range generated in this way and the play difficulty level of the corresponding golf course.

The processor 110 checks whether the second difficulty level of the obstacle factor included in the golf course matches the first difficulty level.

In addition, in the case that the second difficulty level of the obstacle factor does not match the first difficulty level, the processor 110 may display multiple design options in which the number, area, and position of at least one specific obstacle factor are adjusted through the UI and request selection of one of them.

For example, this means that a user requests a golf course design to have a play difficulty level of the first difficulty level, but if the second difficulty level is calculated, there may be a gap with the first difficulty level, and then, a design option is generated to compensate for this, and presented to the user.

At this time, in the case that the construction cost of the golf course is received, the processor 110 may select an obstacle factor with a low construction cost per area among the obstacle factors as a specific obstacle factor.

In one embodiment, in the case that there is a difference between the first difficulty level and the second difficulty level that is greater than a preset threshold, and a construction cost budget is received from the user, the processor 110 may redesign at least one obstacle factor based on the construction cost.

For example, in the case that a construction cost lower than the current design plan is received, the processor 110 may redesign the obstacle factor among the obstacle factors included in the design plan that may lower the design cost while maintaining the difficulty level at the current level.

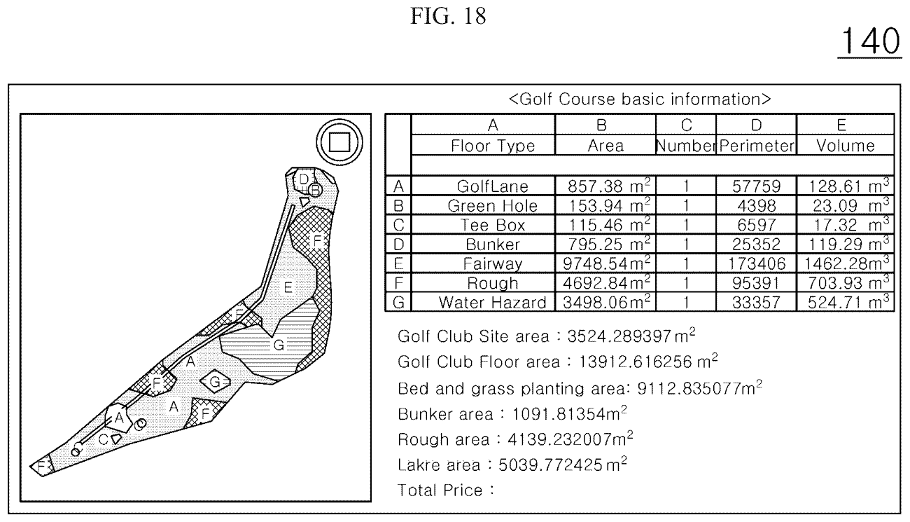

Referring to FIG. 18, the processor 110 may display the name, area, perimeter, and volume of each component through the UI displayed by the display module 140, and may display the area of each component.

Through this, the user may identify the details of the golf course whose design has been completed at a glance.

In one embodiment, the processor 110 may design a golf course based on the first difficulty level and the average play time when an average play time for the golf course is received.

For example, the processor 110 designs each component in the golf course based on the first difficulty level for the golf course in which the outline, the tee box, and the hole cup have already been determined. Then, the processor 110 verifies whether the golf course may complete a game within a requested average play time.

In the case that the verification result shows that the average play time exceeds or falls short of a threshold time, the processor 110 redesigns at least one component.

In one embodiment, the processor 110 may cause an artificial intelligence model to perform a simulation in which the AI model plays a game multiple times using the golf course, and compare the simulation result with the average play time.

The processor 110 may adjust the average play time by redesigning the obstacle factor among the components.

At this time, in the case that the processor 110 determines that the difficulty level of the golf course changes when the obstacle factor is redesigned, the processor 110 may redesign the component other than the obstacle factor. For example, the processor 110 may adjust the distance by adjusting the position of at least one of the tee box and the hole.

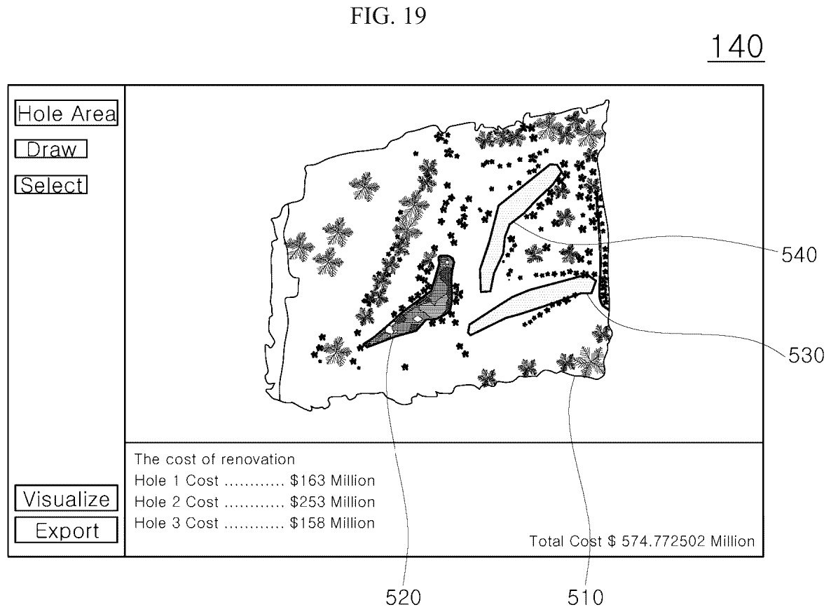

Referring to FIG. 19, the processor 110 displays the map data 510 through the display module 140, and it is exemplified that three golf courses 520, 530, 540 designed in the map data 510 are displayed.

In this way, the golf course automatic generation device 100 may design 1 to 18 golf courses in the received map data 510.

The processor 110 generates BIM data for actually constructing a golf course according to the design details of the components in the designed golf course (step S30).

When the design of the golf course is completed, the processor 110 may generate the BIM data based on the design data. The BIM data generated at this time includes various design information for constructing the golf course.

The company constructing the golf course may check the BIM data generated in this manner, provide an actual estimate, and proceed with construction according to the contract.

In this embodiment, the external server 400 of FIG. 1 may include a construction company server.

The method according to one embodiment of the present disclosure described above may be implemented as a program (or application) to be executed in combination with a hardware server and stored in a medium.

According to the present disclosure, an effect of automatically generating a golf course is provided.

In addition, according to the present disclosure, the components of a first golf course including a tee box, a fairway, and a green can be designed based on source data.

In addition, according to the present disclosure, a difficulty level of a first golf course to be designed can be calculated based on the distance from a tee box to a hole cup, an outline of the first golf course, and a path, and the number, area, and position of obstacle factors related to the difficulty level of the first golf course among the components can be determined based on the calculated difficulty level.

The above-described program may include codes coded in a computer language, such as C, C++, JAVA, or machine language, that may be read by the processor (CPU) of the computer through the device interface of the computer, so that the computer reads the program and executes the methods implemented as a program. Such codes may include functional codes related to functions that define functions necessary for executing the methods, and may include control codes related to execution procedures necessary for the processor of the computer to execute the functions according to a predetermined procedure. In addition, such codes may further include memory reference-related codes regarding which location (address address) of the internal or external memory of the computer should be referenced for additional information or media necessary for the processor of the computer to execute the functions. In addition, in the case that the processor of the computer needs to communicate with any other computer or server located remotely to execute the functions, the code may further include communication-related codes regarding how to communicate with any other computer or server located remotely using the communication module of the computer, what information or media to send and receive during communication, and the like.

The storage medium means a medium that permanently stores data and may be read by a device, rather than a medium that stores data for a short period of time, such as a register, cache, or memory. Specifically, examples of the storage medium include, but are not limited to, ROM, RAM, CD-ROM, magnetic tape, floppy disk, or optical data storage device. That is, the program may be stored in various storage media on various servers that the computer may access, or in various storage media on the user's computer. In addition, the medium may be distributed to a computer system connected to a network, so that a code that may be read by a computer may be stored in a distributed manner.

The steps of a method or algorithm described in connection with the embodiments of the present disclosure may be implemented directly in hardware, implemented in a software module executed by hardware, or implemented by a combination thereof. The software module may reside in a Random Access Memory (RAM), a Read Only Memory (ROM), an Erasable Programmable ROM (EPROM), an Electrically Erasable Programmable ROM (EEPROM), a Flash Memory, a hard disk, a removable disk, a CD-ROM, or any other form of computer-readable recording medium well known in the art to which the present disclosure pertains.

The disclosed embodiments have been described with reference to the attached drawings as described above. Those skilled in the art to which the present disclosure pertains will understand that the present disclosure may be implemented in a form other than the disclosed embodiments without changing the technical idea or essential features of the present disclosure. The disclosed embodiments are exemplary and should not be construed as limiting.

What is claimed is:

1. An electronic device comprising:
a display module;
a memory configured to store at least one process to perform a virtual golf course design operation; and
a processor configured to perform the operation of the process,
wherein the processor is configured to:
display a user interface (hereinafter referred to as ‘UI’) providing a design function of the golf course on the display module,
generate a first golf course based on a design function corresponding to a user operation received through the UI,
render and output at least one VR content for playing a golf game using the generated first golf course,
based on receiving source data for generating the first golf course through the UI, design components of the first golf course including a tee box, a fairway, and a green based on the source data, wherein the source data includes an outline, a path, and an area of the first golf course,
determine a number, an area, and a position of each component included in the first golf course according to the area of the first golf course and a type of the component,
calculate a difficulty level of the first golf course to be designed based on a distance from the tee box to a hole cup, an outline and path of the first golf course, and
determine a number, area, and position of an obstacle factor related to the difficulty level of the first golf course among the components based on the calculated difficulty level.

2. The device of claim 1, the processor is configured to:
based on receiving a golf skill of a user participating in the golf game, determine the number, the area, and the position of each component set as the obstacle factor based on the golf skill of the user,
wherein the golf skill includes at least one of a driving distance, an average score, a fairway landing rate, a green-on success rate, or a putting average of the user.

3. The device of claim 2, wherein the obstacle factor includes a dynamic obstacle factor that is settable and changeable during a play of the golf game,
wherein the dynamic obstacle factor includes a wind speed and a wind direction, and
wherein the processor is configured to:
calculate an evaluation score for multiple items related to the golf skill for each hit of the user according to a progress of the golf game using the first golf course,
based on the calculated evaluation score being determined to be higher than the golf skill of the user during the progress of the golf game using the first golf course, set to activate the dynamic obstacle factor on the first golf course.

4. The device of claim 1, wherein the processor is configured to:
when the user completes playing the golf game using the first golf course, calculate the difficulty level of the user of the first golf course based on a play history, and
modify an obstacle factor setting value of a second golf course for a next game based on a comparison result between the difficulty level of the user of the first golf course and the golf skill of the user.

5. The device of claim 4, wherein the processor is configured to:
based on multiple users being participated in the golf game, identify the play history of at least one first user whose evaluation score for the first golf course is low compared to the golf skills of the multiple users, and
control such that the obstacle factor that causes a decrease in the evaluation score among the play history is deleted, of which weight is reduced, or of which position is changed when the second golf course is designed.

6. The device of claim 5, wherein the processor is configured to:
calculate scores for the multiple items related to the golf skill based on the play history of each of the multiple users,
control such that the component related to the item determined as a weak point of the first user is deleted, of which weight is reduced, or of which position is changed when the second golf course is designed based on the calculated score, and
control such that a weight of the component related to the item determined as a strong point of the first user is increased when the second golf course is designed based on the calculated result.

7. The device of claim 1, wherein the processor is configured to:
based on receiving a target play time for the golf game,
determine the distance from the tee box to the hole cup and an area of the golf course so that the golf game is completed within the target play time based on the golf skill of the user participating in the golf game, and
determine the difficulty level of each component included in the golf course.

8. The device of claim 1, wherein the processor is configured to:
identify a range of adjustable inclination of a batting stand for playing the golf game using the first golf course,
design a terrain of the first golf course within the range of the identified inclination, and
when the golf game is played using the first golf course, control the inclination of the batting stand according to the inclination of the terrain corresponding to a position of a golf ball.

9. The device of claim 1, wherein the processor is configured to:
store first tag information of the component related to the play difficulty level of the golf course used in the golf game in the memory,
calculate evaluation scores for multiple items related to the golf skill of a user who participated in the golf game after the golf game is completed,
store second tag information including the calculated evaluation scores for the multiple items in the memory, and
when designing a golf course for the golf game, determine the golf skill of each user based on the first tag information and the second tag information for at least one previous golf game by searching the play history of each user who participated in the golf game.

10. A method for generating a golf course automatically performed by a hardware processor of an electronic device, comprising:
displaying a user interface (hereinafter referred to as ‘UI’) providing a design function of the golf course on the display module;
generating a first golf course based on a design function corresponding to a user operation received through the UI; and
rendering and outputting at least one VR content for playing a golf game using the generated first golf course,
wherein generating the first golf course comprises:
based on receiving source data for generating the first golf course through the UI, designing components of the first golf course including a tee box, a fairway, and a green based on the source data, wherein the source data includes an outline, a path, and an area of the first golf course;
determining a number, an area, and a position of each component included in the first golf course according to the area of the first golf course and a type of the component;
calculating a difficulty level of the first golf course to be designed based on a distance from the tee box to a hole cup, an outline and path of the first golf course; and
determining a number, area, and position of an obstacle factor related to the difficulty level of the first golf course among the components based on the calculated difficulty level.
